(19) United States
(12) Patent Application Publication
(10) Pub. No.: US 2023/0064356 A1
(43) Pub. Date: Mar. 2, 2023

(54) IMAGE SENSOR BALL GRID ARRAY PACKAGE

(71) Applicant: SEMICONDUCTOR COMPONENTS INDUSTRIES, LLC, Phoenix, AZ (US)

(72) Inventors: Yusheng LIN, Phoenix, AZ (US); Swarnal BORTHAKUR, Boise, ID (US); Larry Duane KINSMAN, Redding, CA (US)

(73) Assignee: SEMICONDUCTOR COMPONENTS INDUSTRIES, LLC, Phoenix, AZ (US)

(21) Appl. No.: 17/822,403

(22) Filed: Aug. 25, 2022

Related U.S. Application Data
(60) Provisional application No. 63/260,702, filed on Aug. 30, 2021.

(51) Int. Cl. H01L 27/146

(52) U.S. Cl. CPC H01L 27/14636; H01L 27/14618; H01L 27/14634; H01L 27/14643; H01L 27/14689; H01L 27/1469; H01L 27/14698; H01L 27/14632; H01L 27/14687

(57) ABSTRACT

A package includes an interposer substrate having at least one through-substrate via (TSV) electrically connecting a top surface of the interposer substrate to a bottom surface of the interposer substrate. The package further includes at least one semiconductor die having a top side, a bottom side, and a sidewall. The at least one semiconductor die is disposed on the interposer substrate with the bottom side electrically coupled to the top surface of the interposer substrate. A molding material is disposed on at least on a portion of the at least one semiconductor die, and an array of conductive material is disposed on the bottom surface of the interposer substrate. The array of conductive material forms the external contacts of the package.

### RELATED APPLICATION

This application claims priority to, and the benefit of U.S. Provisional Patent Application No. 63/260,702, filed Aug. 30, 2021, which is incorporated by reference in its entirety herein.

### TECHNICAL FIELD

This description relates to packaging of semiconductor optical sensors.

### BACKGROUND

Digital image sensors (e.g., a complementary metal-oxide-semiconductor image sensor (CIS) or a charge-coupled device (CCD)) are typically packaged as single die in an integrated circuit (IC) package (i.e., a ceramic ball grid array package (CBGA) or a plastic ball grid array (PBGA) package. However, newer applications (e.g., automotive applications such as advanced driver assistance systems (ADAS) and autonomous driving (AD) systems) need other circuitry (e.g., image signal processor (ISP) or an application-specific integrated circuit (ASIC) die) to be included in the same IC package as the CIS die for improved imaging performance.

### SUMMARY

In a general aspect, a package includes an interposer substrate having at least one through-substrate via (TSV) electrically connecting a top surface of the interposer substrate to a bottom surface of the interposer substrate. The package further includes at least one semiconductor die having a top side, a bottom side, and a sidewall. The at least one semiconductor die is disposed on the interposer substrate with the bottom side electrically coupled to the top surface of the interposer substrate. A molding material is disposed on at least on a portion of the at least one semiconductor die, and an array of conductive material is disposed on the bottom surface of the interposer substrate. The array of conductive material forms the external contacts of the package.

In a general aspect, a package includes an interposer substrate having at least one through-substrate via electrically connecting a top surface of the interposer substrate to a bottom surface of the interposer substrate, at least one semiconductor die disposed on the interposer substrate with a bottom side of the at least one semiconductor die being electrically coupled to the top surface of the interposer substrate, and a layer of molding material disposed on the bottom surface of the interposer substrate. The layer of molding material includes at least one through-mold via for electrical connection to the interposer substrate. An image signal processing (ISP) die is embedded in the layer of molding material, and an array of conductive material is disposed on a bottom surface of the layer of molding material. The array of conductive material forms external contacts of the package.

In a general aspect, a method includes disposing a stack of semiconductor die on a top surface of an interposer substrate. The top surface of the interposer substrate includes contact pads. The method further includes disposing contact pads on a bottom surface of the interposer substrate, and electrically connecting the contact pads on the top surface of interposer substrate and the contact pads on the bottom surface of the interposer substrate. The method further includes disposing an array of conductive material on the contact pads on the bottom surface of the interposer substrate. The array of conductive material forms external contacts of the stack of semiconductor die.

In a general aspect, a method includes disposing a stack of semiconductor die on a top surface of an interposer substrate. The stack of semiconductor die includes an optical sensor die and an application-specific integrated circuit (ASIC) die. The method further includes disposing a molding material to encapsulate the stack of semiconductor die including the optical sensor die and the ASIC die on the top surface of the interposer substrate. The molding material is disposed on sides of the stack above the top surface of interposer substrate and fills in saw street areas of the substrate that have been etched to a depth below the top surface of the interposer substrate. The method further involves thinning the interposer substrate from a backside to expose the molding material filling the saw street areas on a back surface of the interposer substrate and disposing contact pads on the back surface of the interposer substrate.

The method further includes attaching an image signal processor (ISP) die to the back surface of the interposer substrate, disposing an array of conductive material on contact pads not used by the ISP die on a bottom surface of the interposer substrate, and disposing a layer of molding material on the bottom surface of the interposer substrate such that the ISP die, and the array of conductive material disposed the backside of the substrate are embedded in the layer of molding material. The method further includes thinning the layer of molding material disposed on the bottom surface of the interposer substrate from the backside to expose elements of the embedded array of conductive material on a bottom surface of the layer of molding material, and augmenting the elements of the embedded array of conductive material exposed on the bottom surface of the layer of molding with additional conductive material, the embedded array of conductive material forming external input/output contacts of the stack of semiconductor die. The method further includes singulating the interposer substrate (with the encapsulated stack of the optical sensor die and the ASIC die, and the ISP die disposed thereon) to isolate an individual optical sensor package including the optical sensor die, the ASIC die, and the ISP die encapsulated by the mold material.

The details of one or more implementations are set forth in the accompanying drawings and the description below. Other features will be apparent from the description and drawings, and from the claims.

### BRIEF DESCRIPTION OF THE DRAWINGS

FIG. 1 schematically illustrates example imager ball grid array (iBGA) package encapsulated in a molding material

FIG. 2 schematically illustrates an example imager-embedded ball grid array package with an embedded image signal processing (ISP) die.

FIGS. 3A to 3D illustrate an example interposer substrate at different stages of fabrication

FIGS. 4A to 4D illustrate another example interposer substrate at different stages of fabrication.

FIGS. 5A through 5F schematically illustrate an example multi-die optical sensor package at various stages of construction

FIGS. 6A through 6F schematically illustrate another example multi-die optical sensor package at various stages of construction on a substrate.

FIGS. 7A through 7I schematically illustrate an example multi-die optical sensor package at various stages of construction on a substrate.

FIG. 8 illustrates an example method for fabricating an interposer substrate.

FIG. 9 illustrates an example method for fabricating an optical sensor package (e.g., an imager ball grid array (iBGA) package),

FIG. 10 illustrates an example method for fabricating an interposer substrate.

### DETAILED DESCRIPTION

An optical sensor (e.g., a RGB visible light image sensor of a camera, an image sensor) is configured for converting a radiation intensity and color spectrum into electrical signals. In some implementations, optical sensors (including, e.g., digital image sensors) can include devices (e.g., photodiodes) for detecting light intensity. An optical sensor (e.g., a complementary metal-oxide semiconductor (CMOS) pixel sensor) fabricated on a semiconductor die includes an optically active surface area (OASA) with an array of pixels responsible for converting a light and color spectrum into electrical signals. The OASA of an optical sensor may also include, for example, a micro lens array to help funnel incoming light into each pixel (thereby increasing the sensitivity of the image sensor) and/or include a color filter array (CFA) (i.e., a mosaic of tiny color filters coupled to the pixel sensors to capture color information).

The devices of an optical sensor may be fabricated in a semiconductor die (optical sensor die) and coupled to circuitry (e.g., application specific integrated circuits (ASIC) including a driver circuit, A/D convertor, etc.). The ASIC circuits may be fabricated on a same semiconductor die as the devices for detecting light intensity, or on a separate ASIC die coupled to the optical sensor die.

In some implementations, an optical sensor and the associated ASIC circuits can produce an electrical output. The raw image (RAW) data generated by the optical sensor may, for example, be in the form of zeroes and ones for each pixel of the optical sensor array. Further, an image signal processor (ISP) can be a dedicated processor that converts the RAW data generated by the optical sensor into a workable image output through various signal conditioning processes. These various signal conditioning processes may, for example, include one or more of noise reduction, lens shading correction, gamma correction, auto exposure, or auto white balance, etc.

This disclosure describes an optical sensor package integrated with an interposer substrate, and methods for fabricating the optical sensor package integrated with the interposer substrate.

An example optical sensor package encloses an optical sensor die integrated with an interposer substrate. External package connections are disposed on the interposer substrate without using wire bonds to the optical sensor die. The optical sensor die may, for example, be CMOS image sensor (CIS) configured as a chip scale package (CIS CSP). In some implementations, the optical sensor die may be coupled to an ASIC die. The ASIC die may include at least one backside through-semiconductor via (BTSV) for electrical connections to the optical sensor die. The optical sensor die may be arranged as a stack of the optical sensor die and the ASIC die (e.g., a BTSV CIS CSP). The optical sensor die (or the stack of the optical sensor die and the ASIC die) may be disposed on a front surface of the interposer substrate and is connected to a back surface of the interposer substrate by conductive vias extending through the interposer substrate. External input/output terminals for the die enclosed in the optical sensor package are disposed on the back surface of the interposer substrate. In some implementations, the input/output terminals may be arranged, for example, as a ball grid array (BGA) on the back surface of the interposer substrate.

In example implementations, the interposer substrate has a width that is larger than a width of the optical sensor die/ASIC stack in the package and can connect the enclosed optical sensor die/ASIC die stack to a large number of input/outputs of the package through the conductive vias present in the interposer substrate.

In example implementations, the width of interposer substrate can be greater than 120% of the width of the optical sensor die.

In example implementations, the interposer substrate may, for example, be a silicon substrate, and the conductive vias through the interposer substrate may be through-silicon vias (TSVs).

The optical sensor package is further encapsulated in a molding material compound to protect the enclosed devices and structures from the environment (e.g., from humidity or moisture in the environment), and for mechanical (i.e., structural) sturdiness of the package.

An example optical sensor package (hereinafter imager ball grid array (iBGA) package) may include an optical sensor. The optical sensor may, for example, be a digital optical sensor die (e.g., a complementary metal-oxide-semiconductor image sensor (CIS) die, or a charge-coupled device (CCD) die) that can be arranged in a stack with an application specific integrated circuit (ASIC) die. The iBGA package includes a transparent window, cover, or lid (e.g., a glass cover) placed over the stack of the optical sensor die and the ASIC die.

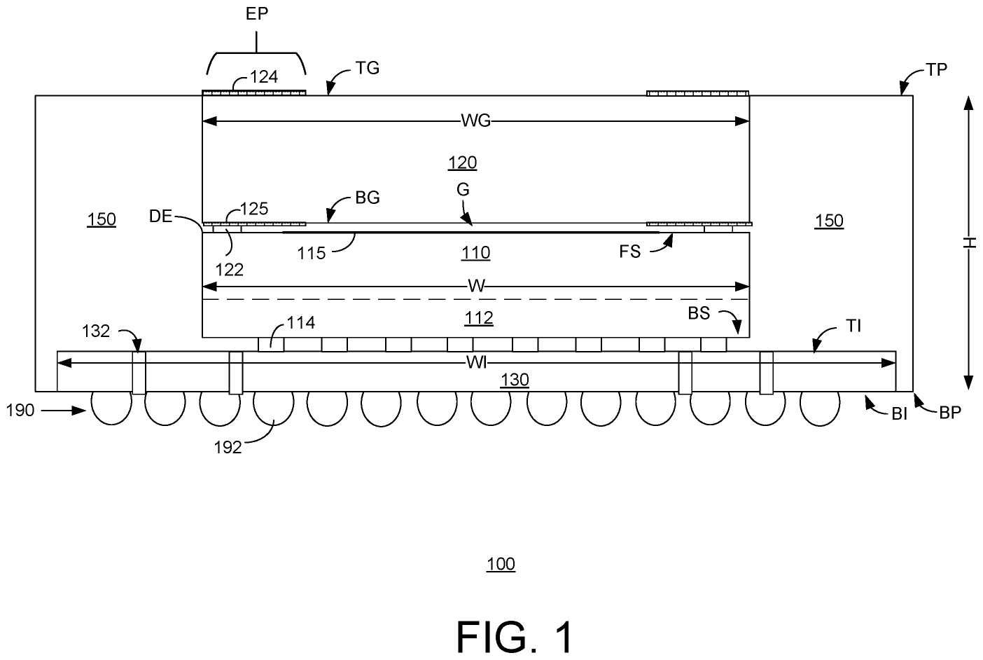

FIG. 1 schematically illustrates an example imager ball grid array (iBGA) package (e.g., iBGA package 100) encapsulated in a mold material, in accordance with the principles of the present disclosure.

As shown in FIG. 1, example iBGA package 100 includes an optical sensor die 110 (e.g., a CIS CSP die) or the optical sensor die 110 coupled to an ASIC die 112 (e.g., a BTSV CSP die). Optical sensor die 110 may have a front surface FS including an optically active surface area (OASA) (e.g., OASA 115). A glass cover (e.g., glass cover 120) is placed over optical sensor die 110 above OASA 115. Glass cover 120 may be attached to optical sensor die 110, for example, by a bead of adhesive material (e.g., dam 122) disposed along edges (e.g., edge DE) on front surface FS of the optical sensor die 110. Although not shown in FIG. 1, the bead of adhesive material (e.g., dam 122) can extend all the way to the edge of the die. Glass cover 120 may be supported above optical sensor die so that there is an air gap (e.g., gap G) between a bottom surface (e.g., surface BG) of the glass cover and the front surface FS of the front surface FS of the optical sensor die 110. Optical sensor die 110 may have a width (e.g., width W) and glass cover 120 may have a width (e.g., width WG) that is a same (or about the same) as the width W of optical sensor die 110.

In some implementations, an edge portion (edge potion EP) of the top surface (e.g., surface TG) of the glass cover may be optionally coupled to (e.g., coated with) a non-transparent light blocking material (e.g., a black paint, mold material, a resin, an epoxy, etc.) (e.g., light blocking material 124). In some implementations, an edge portion of the bottom surface (surface BG) of the glass cover may be optionally coupled to (e.g., coated with) a non-transparent light blocking material (e.g., a black paint, mold material, a resin, an epoxy, etc.) (e.g., light blocking material 125). In some implementations, the bead of adhesive material (e.g., dam 122) can function as light blocking material 125 on the bottom surface (surface BG) of the glass cover. The light blocking material coupled to the edge portion (on either the top surface and/or the bottom surface of the glass cover) may block light from being incident on OASA 115 from side angles and avoid issues with flare in the imager's performance.

As shown in FIG. 1, optical sensor die 110 (e.g., CIS CSP die) or the optical sensor die 110 coupled to ASIC die 112 (e.g., BTSV CSP die) is bonded to a top surface (e.g., surface TI) of interposer substrate 130. The dies may be bonded to conductive traces or pads of a redistribution layer (not shown) in the top surface (e.g., surface TI) of interposer substrate 130 by conductive material 114 (e.g., solder bumps, micro-bumps, copper pillars) disposed on a back surface (e.g., surface BS) of the dies (dies 110/112). Through-substrate vias (e.g., TSV 132) in interposer substrate 130 provide electrical connectivity between the top surface (e.g., surface TI) and a bottom surface (e.g., surface BI) of the interposer substrate. In example implementations, an array (e.g., a ball grid array (BGA)) of conductive material, array 190) is disposed on the bottom surface (e.g., surface BI) of the interposer substrate to provide external input/output terminals of the package. Array 190 of the conductive material may, for example, include (e.g., solder balls 192, copper balls, etc.). Array 190 of conductive material may form the external input/output terminals of the package without using wire bonds to the enclosed die (i.e., optical sensor die 110 and ASIC die 112).

A molding material 150 (e.g., an epoxy molding compound (EMC)) encapsulates the dies and the structures enclosed in iBGA package 100. The package may have a height H between the top surface (e.g., surface TP) and the bottom surface (e.g., surface BP) of the package. As shown in FIG. 1, the top surface (e.g., surface TP) of the package may correspond to the top surface TG of the glass cover 120 and the bottom surface (e.g., surface BP) of the package may correspond to the bottom surface BI of the interposer substrate 130.

In the example iBGA package 100 shown in FIG. 1, molding material 150 (e.g., EMC) is applied to sides of the glass cover, the optical sensor and ASIC dies, and the interposer substrate in the package. The EMC may be applied to the sides extending between a top surface (e.g., surface TP) and a bottom surface (e.g., surface BP) of the package to protect the enclosed structures from, for example, moisture in the environment. Further, the EMC may be an optically non-transparent (e.g., a black or opaque) compound to prevent stray light from entering the pixels and causing flare. The package may have a height H between the top surface (e.g., surface TP) and the bottom surface (e.g., surface BP) of the package. As shown in FIG. 1, the top surface (e.g., surface TP) of the package may correspond to the top surface TG of the glass cover 120 and the bottom surface (e.g., surface BP) of the package may correspond to the bottom surface BI of the interposer substrate 130.

In some example implementations, the principles of encapsulating the semiconductor die (e.g., the optical sensor die, and the ASCI die) disposed on interposer substrate in a mold material (as described above with reference to the iBGA package 100 shown in FIG. 1) can be extended to encapsulate an additional third die (e.g., an ISP die) in the same IC package as the image sensor die 110 and ASIC die 112 for improved imaging performance. The ISP die (or other processor die) can be embedded in a same mold material that encapsulates the image sensor die 110 and ASIC die 112 in the package.

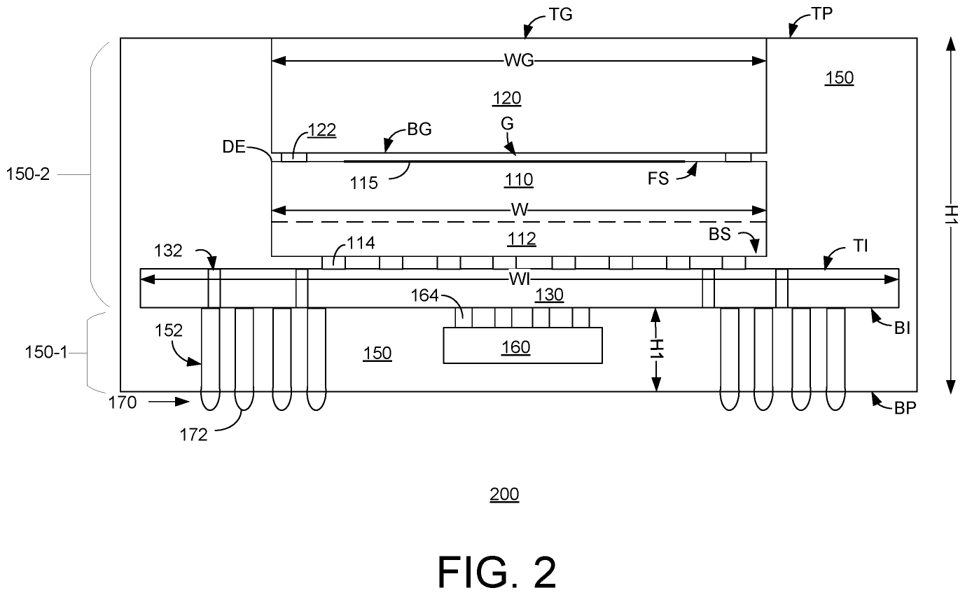

FIG. 2 schematically illustrates an example imager-embedded ball grid array package (e.g., ieBGA package 200) with an ISP die embedded in the mold material encapsulating the image sensor die 110 and ASIC die 112 in the package, in accordance with the principles of the present disclosure.

As shown in FIG. 2, ieBGA package 200 (like the iBGA package 100 shown in FIG. 1) includes glass cover 120 disposed above image sensor die 110 and ASIC die 112. Image sensor die 110 and ASIC die 112 are coupled to interposer substrate 130 by conductive material 114.

ieBGA package 200 further includes an ISP die 160 coupled to interposer substrate 130. In example implementations, ISP die 160 may be flip chip mounted on the bottom surface (e.g., surface BI) of the interposer substrate. Conductive material 164 (e.g., solder balls, copper pillars) may electrically connect ISP die to traces and contact pads (not shown) in interposer substrate 130. ISP die 160 is embedded in a layer 150-1 of molding material 150 disposed on the bottom surface (e.g., surface BI) of the interposer substrate. Layer 150-1 of the molding material may have a height of thickness H1 between the bottom surface (e.g., surface BI) of the interposer substrate and the bottom surface (e.g., surface BP) of the package.

In example implementations, a through mold via (TMV) (e.g., TMV 152) extending across layer 150-1 between surface BI and surface BP may provide a passage for connections between a top surface (e.g., surface BI) and a bottom surface (e.g., surface BP) of across layer 150-1. In example implementations, an array (e.g., a ball grid array (BGA)) of conductive material (e.g., array 170) is disposed on the bottom surface (e.g., surface BI) of the layer 150-1 to provide external input/output terminals of the package. The conductive material of array 170 may, for example, include (e.g., solder balls 172, copper balls, etc.). Array 170 of conductive material may form the external input/output terminals of the package without using wire bonds to the enclosed die (i.e., optical sensor die 110, ASIC die 112 and ISP die 160).

A layer 150-2 of molding material 150 (e.g., EMC) is applied to sides of the glass cover, the optical sensor and ASIC dies, and the interposer substrate in the package. This layer (i.e., layer 150-2) may be applied to the sides extending between the top surface (e.g., surface TP) of the package and the bottom surface (e.g., surface BI) of the interposer substrate. The layers (i.e., layer 150-1 and layer 150-2) of molding material 150 can encapsulate the devices and structures of the package from all six sides (i.e., a top side, a bottom side and four vertical sides (can each be referred to as sidewalls)). The molding material (molding material 150) in the package, can protect the enclosed device and structures from, for example, moisture in the environment. Further, the molding material (molding material 150) may be an optically non-transparent (e.g., a black or opaque) compound to prevent stray light from entering the pixels and causing flare.

The interposer substrate (e.g., interposer substrate 130) used in the optical sensor packages (e.g., iBGA package 100, FIG. 1, and ieBGA package 200 FIG. 2) can be fabricated by using wafer-level processes for either via last scenario or via first (or middle) scenario for assembly of the optical sensor packages (e.g., iBGA package 100, FIG. 1; and ieBGA package 200 FIG. 2).

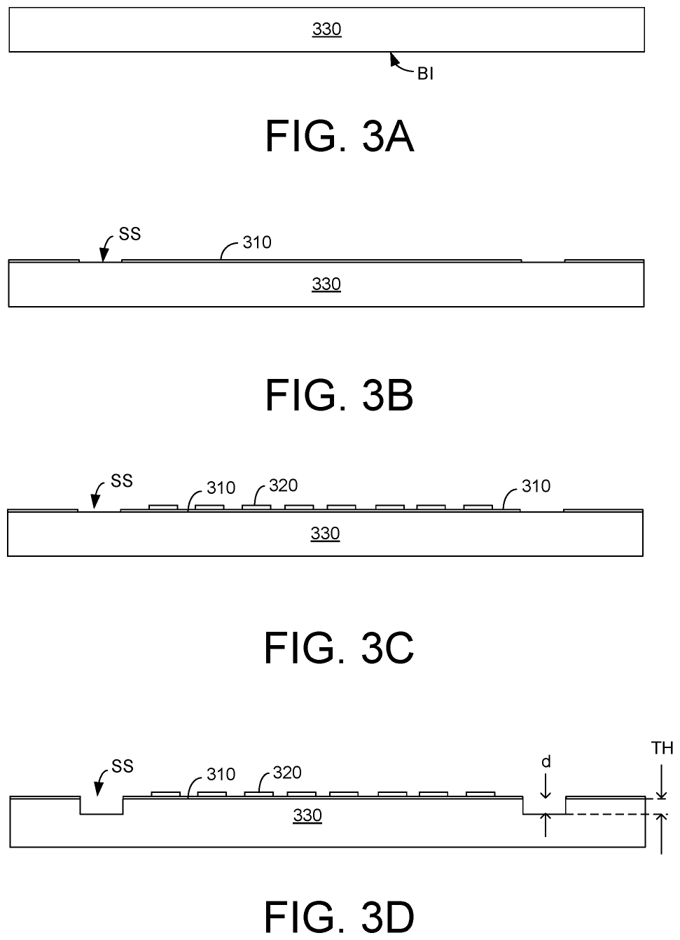

FIGS. 3A to 3D show cross-sectional views of an interposer substrate at different stages of fabrication for use in the via last scenario for assembly of the optical sensor packages. FIG. 3A shows a blank substrate 330 (e.g., a blank semiconductor wafer, a blank silicon wafer) used a starting substrate for the fabrication. FIG. 3B shows an oxide layer 310 grown and patterned on a top surface TI of the blank substrate. Areas of the substrate (e.g., saw street areas SS) identified to be cut (in the later fabrication of the optical sensor packages) may not be overgrown with oxide layer 310. FIG. 3C shows patterned conductive traces and pads (e.g., circuitry 320) formed on oxide layer 310. Circuitry 320 may include multiple levels of metallization (e.g., M1, M2, M3 levels) with multiple levels of dielectric layers (e.g., nitride, oxide, polymer, etc.) between the multiple levels of metallization (not shown). Next, interposer substrate 330 may be thinned to a target semiconductor thickness. FIG. 3D shows interposer substrate 330 after areas of the substrate (e.g., saw street areas SS) identified to be cut (in the later fabrication of the optical sensor packages) have been partially etched to a depth d corresponding to a target semiconductor thickness (e.g., thickness TH) (e.g., within ±10 μm).

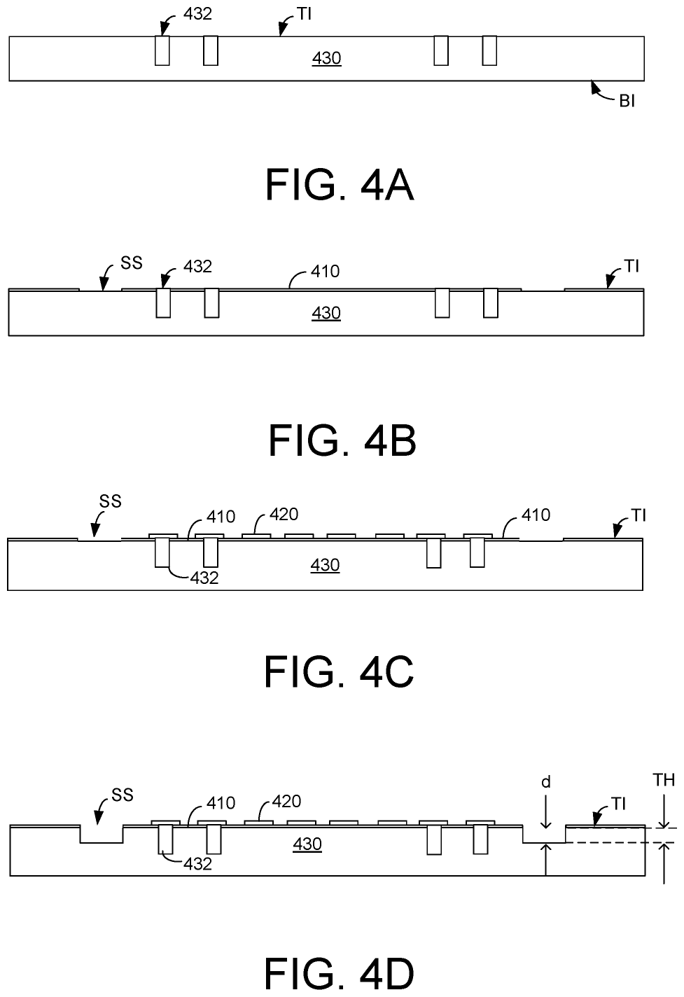

FIGS. 4A to 4D show cross-sectional views of an interposer substrate at different stages of fabrication for use in the via first or middle scenario for assembly of the optical sensor packages. FIG. 4A shows a substrate 430 (e.g., a semiconductor wafer, a silicon wafer) used a starting substrate for the fabrication. Starting substrate 430 may already have through-semiconductor vias (e.g., TSV 432) already patterned and etched in the substrate. FIG. 4B shows an oxide layer 410 grown and patterned on a top surface TI of the starting substrate. Areas of the substrate (e.g., saw street areas SS) identified to be cut (in the later fabrication of the optical sensor packages) may not be overgrown with oxide layer 410. FIG. 4C shows patterned circuitry, i.e., conductive traces and pads (e.g., contact pads 420) formed on oxide layer 410. The patterned circuitry (e.g., contact pads 420) may include multiple levels of metallization (e.g., M1, M2, M3 levels) with multiple levels of dielectric layers (e.g., nitride, oxide, polymer, etc.) between the multiple levels of metallization (not shown). Next, interposer substrate 430 may be thinned to a target semiconductor thickness. FIG. 4D shows interposer substrate 430 after areas of the substrate (e.g., saw street areas SS) identified to be cut (in the later fabrication of the optical sensor packages) have been partially etched to a depth d corresponding to a target semiconductor thickness (e.g., thickness TH) (e.g., within ±10 μm).

Either interposer substrate 330 (FIG. 3D) and interposer substrate 430 (FIG. 4D) may be used, for example, as the interposer substrate (e.g., interposer substrate 130) in the assembly of the optical sensor packages (e.g., iBGA package 100, FIG. 1; and ieBGA package 200 FIG. 2).

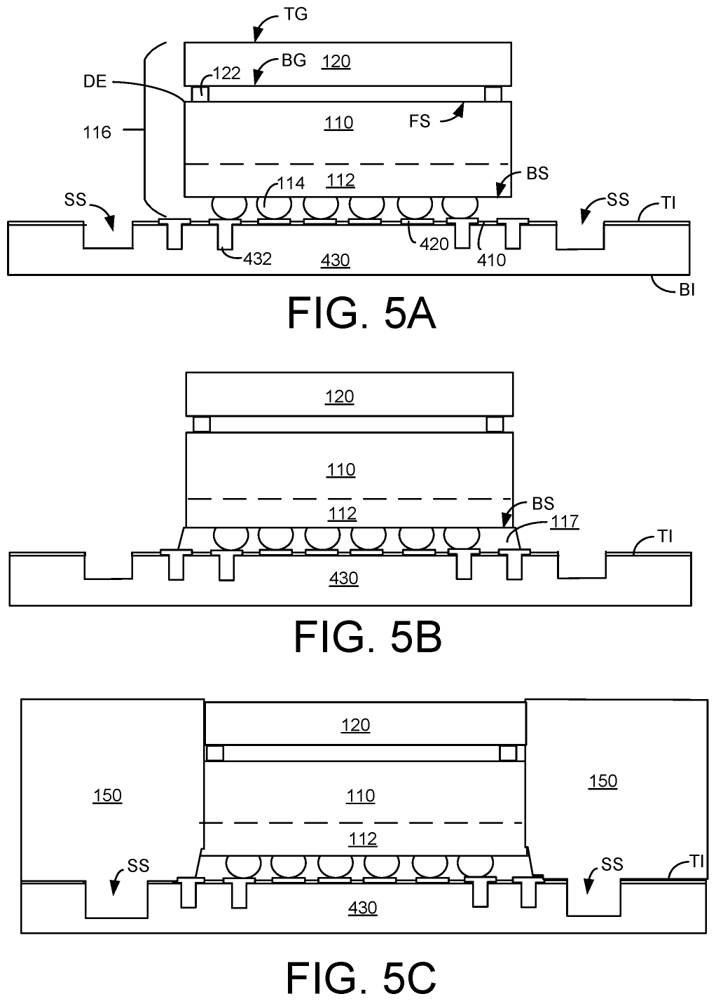

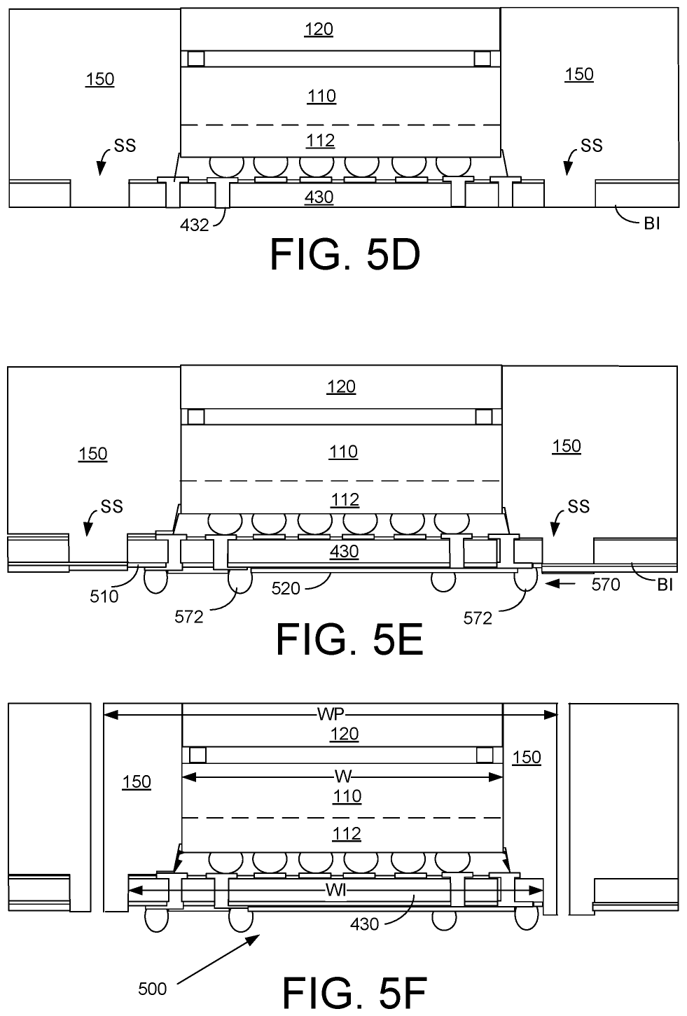

FIGS. 5A through 5F schematically illustrate a multi-die optical sensor package 500 (e.g., a package like an iBGA package 100, FIG. 1) at different stages of construction on a substrate (e.g., interposer substrate 430) in a via first scenario (i.e., with interposer substrate 430 having built-in TSVs).

Multi-die optical sensor package 500 may, for example, include a stack (e.g., stack 116) of an optical sensor die 110 (e.g., a CIS CSP die) coupled to an ASIC die 112. Stack 116 includes a glass cover (e.g., glass cover 120) placed over the optical sensor die 110. The glass cover (e.g., glass cover 120) may be attached to optical sensor die 110, for example, by a bead of adhesive material (e.g., dam 122) disposed along edges (e.g., edge DE) on front surface FS of the optical sensor die 110. The ASIC die coupled to the optical sensor die may include backside through-semiconductor vias (BTSV) (not shown) for electrical connections to the optical sensor die. Stack 116 (including optical sensor die 110 coupled to ASIC die 112) can be configured as a BGA package (e.g., a BTSV CIS CSP) with a ball grid array of conductive material (e.g., solder balls) disposed on a back surface (e.g., surface BS) of the stack of dies (dies 110/112).

FIG. 5A shows multi-die optical sensor package 500 at a first stage of construction in which stack 116 is placed on an interposer substrate (e.g., interposer substrate 430, FIG. 4D). The interposer substrate (e.g., interposer substrate 430, FIG. 4D) may have via first TSVs (e.g., TSV 432) formed on a top surface (e.g., surface TI) of the substrate. In the first stage of construction, the ball grid array of conductive material 114 on the bottom surface BS of stack 116 is aligned with the conductive traces and contact pads (e.g., contact pads 420) on top surface (surface TI) of interposer substrate 430 between areas of the substrate (e.g., saw street areas SS) identified to be cut in later stages of construction of the package. Stack 116 can be bonded to the conductive traces and contact pads (e.g., contact pads 420) by the conductive material 114 (e.g., solder ball, solder bump, micro-bump, or hybrid bond, etc.).

FIG. 5B shows multi-die optical sensor package 500 at a second stage of construction. In this second stage of construction, an underfill material (e.g., underfill 117) may be disposed in open spaces between bottom surface BS of stack 116 and top surface TI of interposer substrate 430. The underfill material (e.g., underfill 117) may, for example, be a resin, an epoxy, or a molding compound.

FIG. 5C shows multi-die optical sensor package 500 at a third stage of construction. In this third stage of construction, a molding material 150 (e.g., an epoxy molding compound (EMC)) encapsulates stack 116 (including optical sensor die 110 and ASIC die 112). The molding compound is disposed on all four sides of stack 116 above top surface TI of interposer substrate 430. The molding compound may also be disposed in the areas of the substrate (e.g., saw street areas SS) that have been etched to a depth d below top surface TI of interposer substrate 430.

FIG. 5D shows multi-die optical sensor package 500 at a fourth stage of construction. In this fourth stage of construction, interposer substrate 430 is thinned (e.g., etched) from the backside to expose the TSVs (e.g., TSV 432) and the molding compound filling the saw street areas (e.g., saw street areas SS) on back surface BI of the substrate.

FIG. 5E shows multi-die optical sensor package 500 at a fifth stage of construction. In this fifth stage of construction, a passivation layer (e.g., layer 510) (e.g., an oxide, nitride, or polymer) is disposed on back surface BI of the substrate. Further, a redistribution layer (including at least a metallization level and traces and conductive pads) (e.g., conductive pad 520) is formed on the passivation layer (e.g., layer 510). The RDL may include an under-bump metallization (UMB) layer. A ball grid array (BGA)) of conductive material (e.g., array 570) is disposed on a RDL surface (e.g., on conductive pad 520) to provide external input/output terminals of the package. The conductive material of array 570 may, for example, include (e.g., solder balls 572, copper balls, etc.). Array 570 of the conductive material may form the external input/output terminals of the package without using wire bonds to the enclosed die (i.e., optical sensor die 110 and ASIC die 112).

FIG. 5F shows multi-die optical sensor package 500 at a sixth stage of construction. In this sixth stage of construction, the structure shown in FIG. 5D is singulated through saw street areas SS to isolate an individual multi-die optical sensor package 500. The individual multi-die optical sensor package 500 includes optical sensor die 110 and ASIC die 112 encapsulated in molding material 150. The individual multi-die optical sensor package 500 may have a package width WP, and include optical sensor die 110 having a width W supported on interposer substrate 430 having a width WI.

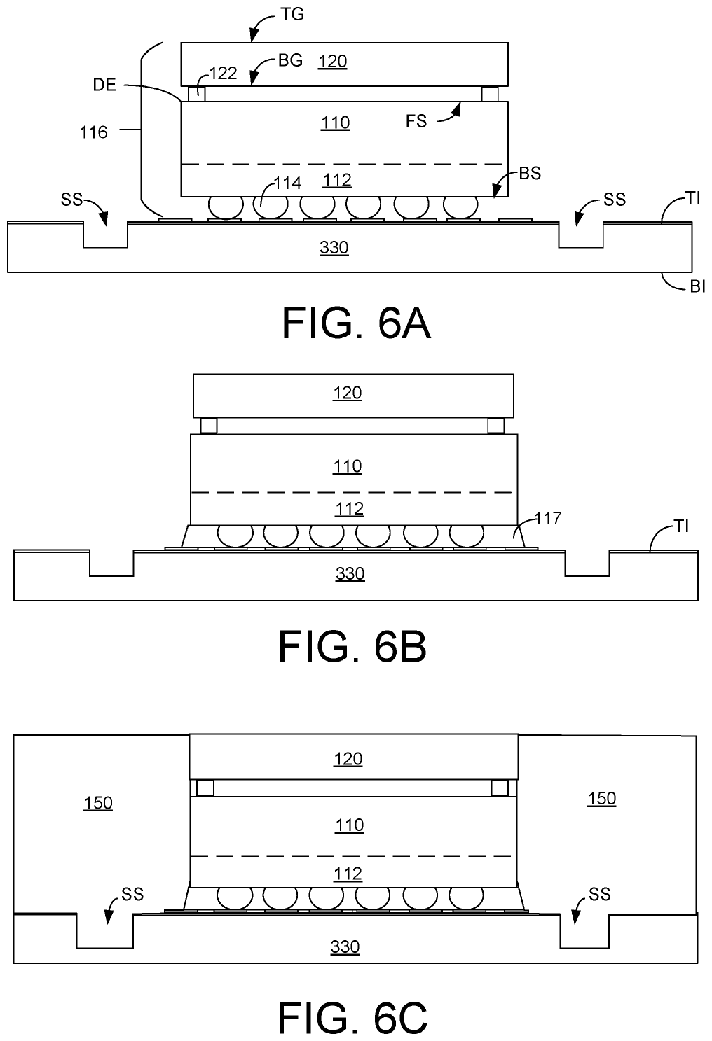

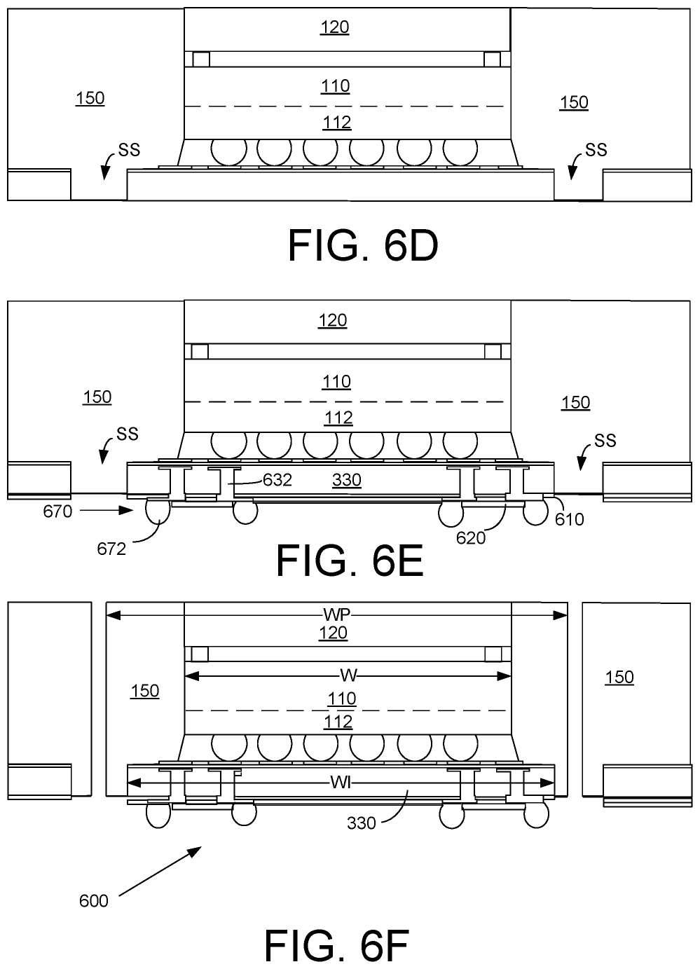

FIGS. 6A through 6F schematically illustrate a multi-die optical sensor package 600 (e.g., a package like an iBGA package 100, FIG. 1) at various stages of construction on a substrate (e.g., interposer substrate 330) in a via last scenario (i.e., with TSVs built in interposer substrate 330 in the last stages of construction of a multi-die optical sensor package 600).

Like multi-die optical sensor package 500, multi-die optical sensor package 600 may, for example, include a stack (e.g., stack 116) of an optical sensor die 110 (e.g., a CIS CSP die) coupled to an ASIC die 112, and a glass cover (e.g., glass cover 120) placed over the optical sensor die 110. The ASIC die coupled to the optical sensor die may include backside through-semiconductor vias (BTSV) (not shown) for electrical connections to the optical sensor die. Stack 116 (including optical sensor die 110 coupled to ASIC die 112) can be configured as a BGA package (e.g., a BTSV CIS CSP) with a ball grid array of conductive material (e.g., solder balls) disposed on a back surface (e.g., surface BS) of the stack of dies (dies 110/112).

FIG. 6A shows multi-die optical sensor package 600 at a first stage of construction in which stack 116 is placed on an interposer substrate (e.g., interposer substrate 330, FIG. 3D). In the first stage of construction, the ball grid array of conductive material 114 on the bottom surface BS of stack 116 is aligned with the conductive traces and contact pads (e.g., contact pads 420) on top surface (surface TI) of interposer substrate 330 between areas of the substrate (e.g., saw street areas SS) identified to be cut in later stages of construction of the package.

FIG. 6B shows multi-die optical sensor package 600 at a second stage of construction. In this second stage of construction, an underfill material (e.g., underfill 117) may be disposed in open spaces between bottom surface BS of stack 116 and top surface TI of interposer substrate 330.

FIG. 6C shows multi-die optical sensor package 600 at a third stage of construction. In this third stage of construction, a molding material 150 (e.g., an epoxy molding compound (EMC)) encapsulates stack 116 (including optical sensor die 110 and ASIC die 112). The molding compound is disposed on all four sides of stack 116 above top surface TI of interposer substrate 330. The molding compound may also be disposed in the areas of the substrate (e.g., saw street areas SS) that have been etched to a depth d below top surface TI of interposer substrate 330. Further, the molding material (molding material 150) may be an optically non-transparent (e.g., a black or opaque) compound to prevent stray light from entering the pixels and causing flare.

FIG. 6D shows multi-die optical sensor package 600 at a fourth stage of construction. In this fourth stage of construction, interposer substrate 330 is thinned (e.g., etched) from the backside to expose the molding compound filling the saw street areas (e.g., saw street areas SS) on back surface BI of the substrate.

FIG. 6E shows multi-die optical sensor package 600 at a fifth stage of construction. In this fifth stage of construction, back side through-semiconductor vias (e.g., TSV 632) are formed through interposer substrate 330. Further, a passivation layer (e.g., layer 610) (e.g., an oxide, nitride, or polymer) is disposed on back surface BI of the substrate. Further, a redistribution layer (including at least one metallization level and traces and conductive pads) (e.g., conductive pad 620) is formed on the passivation layer (e.g., layer 610). The RDL may include an under-bump metallization (UMB) layer. A ball grid array (BGA)) of conductive material (e.g., array 670) is disposed on a RDL surface (e.g., on conductive pad 620) to provide external input/output terminals of the package. The conductive material of array 670 may, for example, include (e.g., solder balls 672, copper balls, etc.). Array 670 of conductive material may form the external input/output terminals of the package without using wire bonds to the enclosed die (i.e., optical sensor die 110 and ASIC die 112).

FIG. 6F shows multi-die optical sensor package 600 at a sixth stage of construction. In this sixth stage of construction, the structure shown in FIG. 6E is singulated through saw street areas SS to isolate an individual multi-die optical sensor package 600. The individual multi-die optical sensor package 600 includes optical sensor die 110 and ASIC die 112 encapsulated in molding material 150. The individual multi-die optical sensor package 600 may have a package width WP, and include optical sensor die 110 having a width W supported on interposer substrate 330 having a width WI.

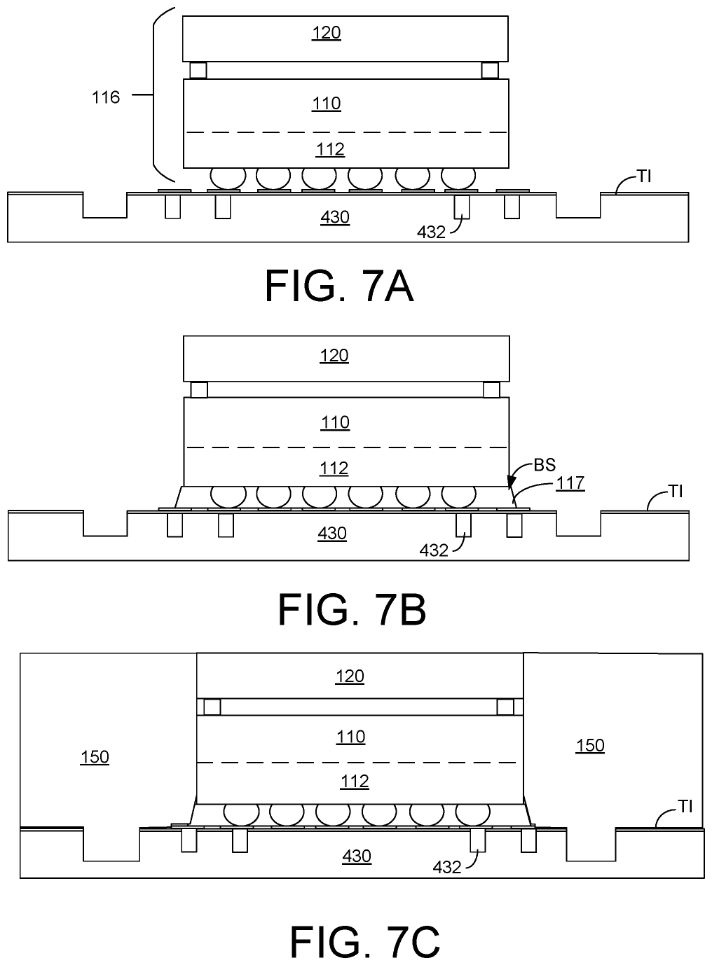

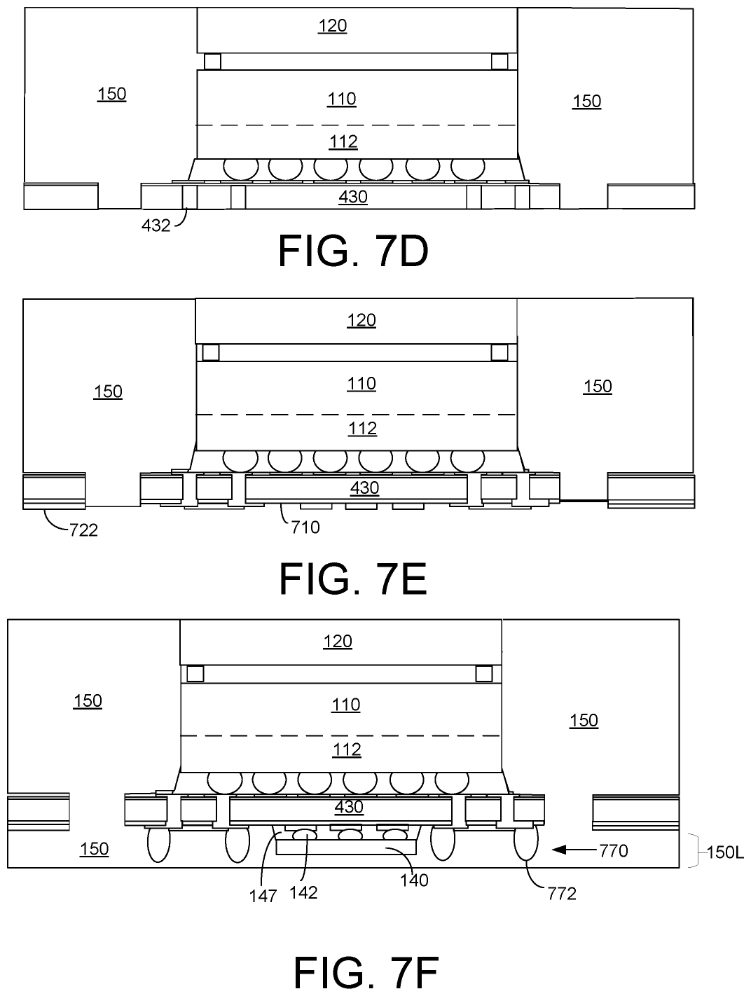

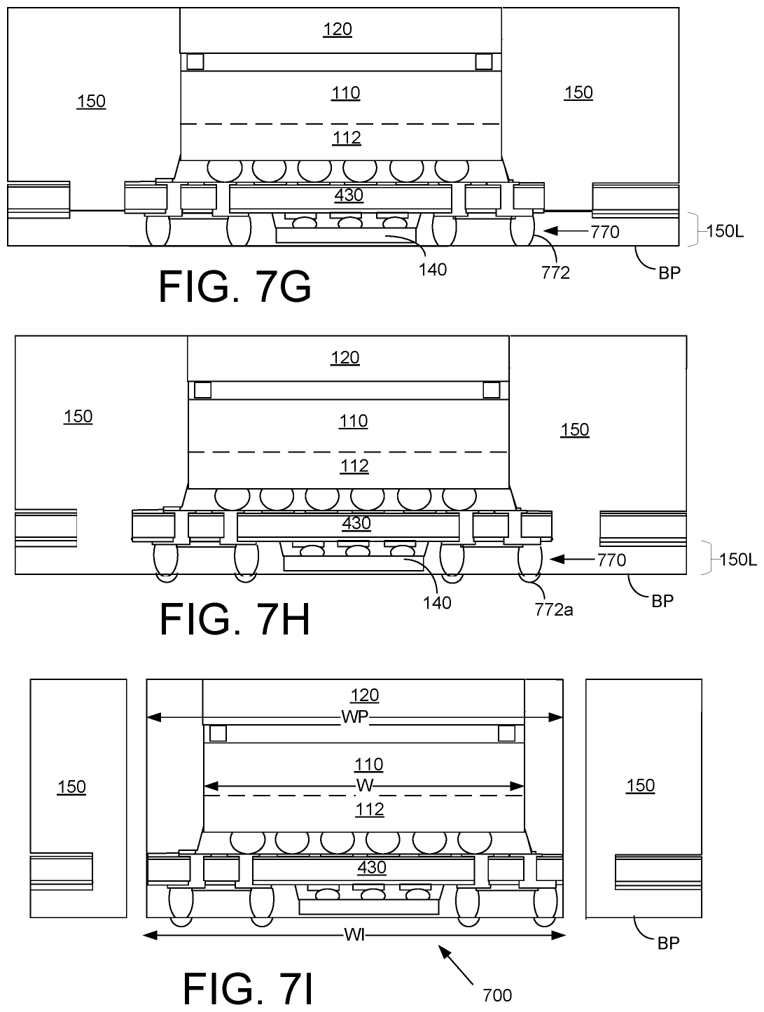

FIGS. 7A through 7F schematically illustrate a multi-die optical sensor package 700 (e.g., a package like ieBGA package 200, FIG. 2 that encapsulates three dies i.e., an image sensor die, an ASIC die, and an ISP die) at different stages of construction on a substrate (e.g., interposer substrate 430). The examples shown in a via first scenario (i.e., with interposer substrate 330 having built-in TSVs) but are also applicable in a via last scenario.

Multi-die optical sensor package 700 may, for example, include a stack (e.g., stack 116) of an optical sensor die 110 (e.g., a CIS CSP die) coupled to an ASIC die 112. Stack 116 may include a glass cover (e.g., glass cover 120) placed over the optical sensor die 110. The glass cover (e.g., glass cover 120) may be attached to optical sensor die 110, for example, by a bead of adhesive material (e.g., dam 122) disposed along edges (e.g., edge DE) on front surface FS of the optical sensor die 110. The ASIC die coupled to the optical sensor die may include at least one backside through-semiconductor via (BTSV) (not shown) for electrical connections to the optical sensor die. Stack 116 (including optical sensor die 110 coupled to ASIC die 112) can be configured as a BGA package (e.g., a BTSV CIS CSP) with a ball grid array of conductive material (e.g., solder balls) disposed on a back surface (e.g., surface BS) of the stack of dies (dies 110/112).

FIG. 7A shows multi-die optical sensor package 700 at a first stage of construction in which stack 116 is placed on an interposer substrate (e.g., interposer substrate 430, FIG. 4D). The interposer substrate (e.g., interposer substrate 430, FIG. 4D) may have via first TSVs (e.g., TSV 432) formed on a top surface (e.g., surface TI) of the substrate. In the first stage of construction, the ball grid array of conductive material 114 on the bottom surface BS of stack 116 is aligned with the conductive traces and contact pads (e.g., contact pads 420) on top surface (surface TI) of interposer substrate 430 between areas of the substrate (e.g., saw street areas SS) identified to be cut in later stages of construction of the package. Stack 116 can be bonded to the conductive traces and contact pads (e.g., contact pads 420) by the conductive material 114 (e.g., solder ball, solder bump, micro-bump, or hybrid bond, etc.).

FIG. 7B shows multi-die optical sensor package 700 at a second stage of construction. In this second stage of construction, an underfill material (e.g., underfill 117) may be disposed in open spaces between bottom surface BS of stack 116 and top surface TI of interposer substrate 430. Underfill 117 may, for example, be a resin, an epoxy, or a molding compound.

FIG. 7C shows multi-die optical sensor package 700 at a third stage of construction. In this third stage of construction, a molding material 150 (e.g., an epoxy molding compound (EMC)) encapsulates stack 116 (including optical sensor die 110 and ASIC die 112). The molding compound is disposed on all four sides of stack 116 above top surface TI of interposer substrate 430. The molding compound may also be disposed in the areas of the substrate (e.g., saw street areas SS) that have been etched to a depth d below top surface TI of interposer substrate 430. Further, the molding material (molding material 150) may be an optically non-transparent (e.g., a black or opaque) compound to prevent stray light from entering the pixels and causing flare.

FIG. 7D shows multi-die optical sensor package 700 at a fourth stage of construction. In this fourth stage of construction, interposer substrate 430 is thinned (e.g., etched) from the backside to expose the TSVs (e.g., TSV 432) and the molding compound filling the saw street areas (e.g., saw street areas SS) on back surface BI of the substrate.

FIG. 7E shows multi-die optical sensor package 700 at a fifth stage of construction. In this fifth stage of construction, a passivation layer (e.g., layer 710) (e.g., an oxide, nitride, or polymer) is disposed on back surface BI of the substrate. Further, a redistribution layer (including at least a metallization level and traces and conductive contact pads) (e.g., conductive pad 722) is formed on the passivation layer (e.g., layer 710). The RDL may include an under-bump metallization (UMB) layer.

FIG. 7F shows multi-die optical sensor package 700 at a sixth stage of construction. In this sixth stage of construction, an ISP die (e.g., ISP die 140 is disposed on a RDL surface (e.g., on a contact pad, conductive pad 722) on the back surface BI of the substrate. ISP die may be attached to the RDL contact pads (e.g., conductive pad 722) using conductive material (e.g., solder balls, micro bumps, copper balls, etc.) (e.g., solder balls 142). An underfill material (e.g., underfill 147) may fill spaces between solder balls 142, ISP die 140, and the passivation layer (e.g., layer 710) disposed on back surface BI of the substrate.

Further, in this sixth stage of construction, a ball grid array (BGA)) of conductive material (e.g., array 770) is disposed on a RDL surface (e.g., on a contact pad, conductive pad 722) to form precursors of external input/output terminals of the package. The conductive material of array 770 may, for example, include (e.g., solder balls 772, copper balls, etc.). Array 770 of conductive material may form the external input/output terminals of the package without using wire bonds to the enclosed die (i.e., optical sensor die 110, ASIC die 112, and ISP die 140).

Further, in this sixth stage of construction, a layer (e.g., layer 150L) of molding material (e.g., molding material 150) may be disposed on back surface BI of the substrate so that ISP die 140 and the conductive material structures (e.g., array 770, solder balls 772) disposed on the backside of the substrate are embedded in the molding material (e.g., molding material 150). The molding material may, for example, be a liquid molding compound (LMC) or an epoxy mold compound (EMC). Either transfer mold or compression mold processes may be used to form the layer of molding material (e.g., layer 150L) embedding the ISP die 140 on the back side of the substrate. Further, the molding material (molding material 150) may be an optically non-transparent (e.g., a black or opaque) compound to prevent stray light from entering the pixels and causing flare.

FIG. 7G shows multi-die optical sensor package 700 at a seventh stage of construction. In this seventh stage of construction, the layer of molding material (e.g., layer 150L) embedding the ISP die 140 on the back side of the substrate is thinned (i.e., mechanically ground or laser ablated) from the backside to expose solder balls 772 on the bottom surface (e.g., surface BP) of the package.

FIG. 7H shows multi-die optical sensor package 700 at a seventh stage of construction. In this seventh stage of construction, an additional volume of solder (e.g., solder 772a) is disposed on solder balls 772 that are exposed on the bottom surface (e.g., surface BP) of the package.

The conductive material of array 770 including solder balls 772 that are enhanced with the additional volume of solder (e.g., solder 772a) may form the external input/output terminals of the package without using wire bonds to the enclosed die (i.e., optical sensor die 110, ASIC die 112, and ISP die 140) in the package.

FIG. 7I also shows that the assembled structure (with the conductive material of array 770 forming the external input/output terminals of the package) is singulated through saw street areas SS to isolate an individual multi-die optical sensor package 700. The individual multi-die optical sensor package 700 includes optical sensor die 110, ASIC die 112, and ISP die 140 encapsulated in molding material 150. The individual multi-die optical sensor package 700 may have a package width WP, and include optical sensor die 110 having a width W supported on interposer substrate 430 having a width WI.

In the packages described in the foregoing (e.g., package 100, 200, 500, 600, and 700), the glass cover (e.g., glass cover 120) may present a clear glass surface over a full width of the glass cover above the optical sensor die for passage of light incident on the OASA of the optical sensor die. In some implementations of the packages (e.g., package 100, 200, 500, 600, and 700, etc.), an edge portion of the top surface of the glass cover may be coated with a non-transparent light blocking material (e.g., a black paint, mold material, etc.) as shown, for example, in package 100, FIG. 1. In some implementations, an edge portion of the bottom surface of the glass cover may be coated with a non-transparent light blocking material (e.g., a black paint, mold material, etc.). The light blocking material coupled to the edge portion (on either the top surface and/or the bottom surface of the glass cover) may block light from being incident on the OASA from side angles and avoid issues with flare in the imager's performance.

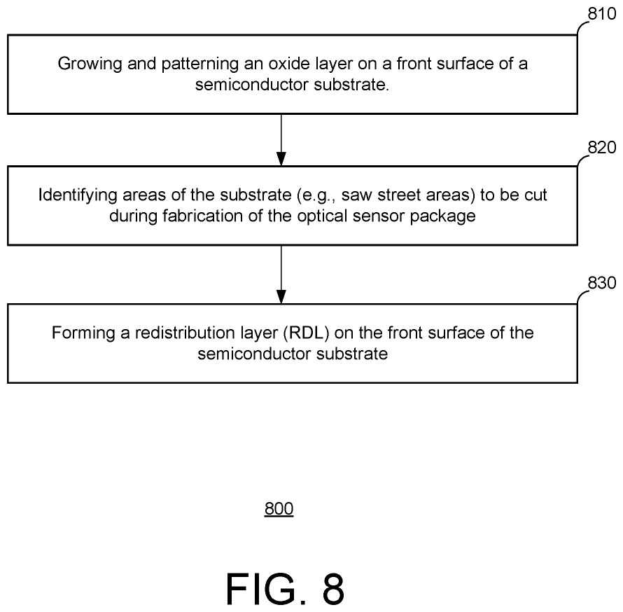

FIG. 8 illustrates an example method 800 for fabricating an interposer substrate. The fabricated interposer substrate can be used to support semiconductor die in an optical sensor package, for example, an imager embedded ball grid array package including an optical sensor die and an ASIC die, or an imager-embedded ball grid array package further including an embedded image signal processing (ISP) die.

Method 800 includes growing and patterning an oxide layer on a front surface of a semiconductor substrate (810), and identifying areas of the substrate (e.g., saw street areas) to be cut during fabrication of the optical sensor package (820). Method 800 further includes forming a redistribution layer (RDL) on the front surface of the semiconductor substrate (830). The redistribution layer can include patterned conductive traces and pads formed at least one level of metallization (e.g., M1, M2, M3 level, etc.). Method 800 may include thinning the semiconductor substrate to a target semiconductor substrate thickness.

In method 800, growing and patterning the oxide layer on the front surface of the semiconductor substrate 810 may include patterning and etching at least one through-semiconductor via (TSV) in the semiconductor substrate. The TSV (filled with conductive material) can electrically connect the front surface to the back surface of the semiconductor substrate.

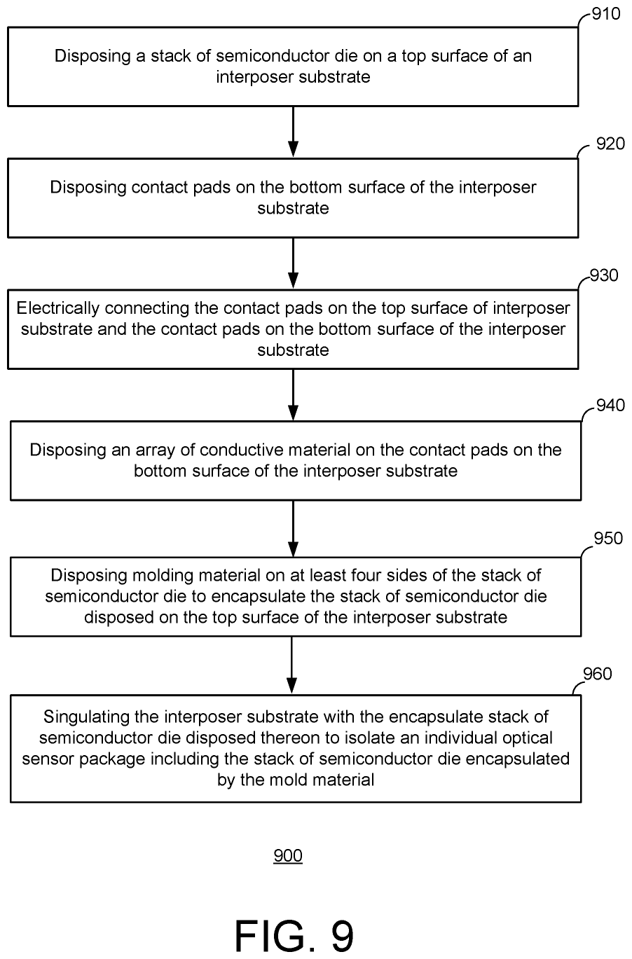

FIG. 9 shows an example method 900 for fabricating an optical sensor package (e.g., an imager ball grid array (iBGA) package) including a stack of semiconductor die. The stack of semiconductor die may include an optical sensor die disposed above and coupled to an ASIC die. The optical sensor die may, for example, be a contact image sensor (CIS) configured as a chip scale package (CIS CSP). The ASIC die may include backside through-semiconductor vias (BTSV) for electrical connections to the optical sensor die. The optical sensor die may be arranged as a stack of the optical sensor die and the ASIC die (e.g., a BTSV CIS CSP).

Method 900 includes disposing a stack of semiconductor die on a top surface of an interposer substrate (910). The stack of semiconductor die may, for example, include an optical sensor die coupled to an ASIC die. The stack of semiconductor die may further include an array (e.g., BGA) of conductive material disposed on a bottom surface of the stack.

Disposing the stack of semiconductor die on the top surface of the interposer substrate 910 may include aligning the array of conductive material disposed on the bottom surface of the stack with contact pads disposed on the top surface of interposer substrate and bonding the stack to the contact pads on the top surface of interposer substrate using the array of conductive material disposed on the bottom surface of the stack. The bonding by the conductive material may involve solder ball, solder bump, micro-bump, or hybrid bond.

After bonding, method 900 may include disposing an underfill material in open spaces between the bottom surface BS of the stack and a top surface TI of the interposer substrate.

Method 900 further includes disposing contact pads on the bottom surface of the interposer substrate (920), electrically connecting the contact pads on the top surface of interposer substrate and the contact pads on the bottom surface of the interposer substrate (930) and disposing an array of conductive material on the contact pads on the bottom surface of the interposer substrate (940). The array of conductive material (e.g., solder bumps, micro bumps, copper balls, etc.) disposed on the contact pads on the bottom surface of the interposer substrate can form the external input/output contacts of the package.

Method 900 further includes disposing molding material on at least four sides of the stack of semiconductor die to encapsulate the stack of semiconductor die disposed on the top surface of the interposer substrate (950), and singulating the interposer substrate with the encapsulate stack of semiconductor die disposed thereon to isolate an individual optical sensor package including the stack of semiconductor die encapsulated by the mold material (960).

In method 900, singulating the interposer substrate with the encapsulated stack of semiconductor die disposed thereon includes singulating through pre-identified saw street areas on the interposer substrate.

In method 900, electrically connecting the contact pads on the top surface of interposer substrate and the contact pads on the bottom surface of the interposer substrate 930 may include utilizing electrically conductive TSVs for electrically connecting the top surface of interposer substrate and the bottom surface of the interposer substrate.

In some example implementations, under a via first scenario, the TSVs may be prebuilt and extend from the front surface of the interposer substrate partially through a thickness of the interposer substrate toward a back surface of the interposer substrate. In such implementations, in method 900, disposing contact pads on the bottom surface of the interposer substrate 920, includes thinning the interposer substrate from a backside to expose the TSVs on the bottom surface of the interposer substrate.

In some implementations, under a via last or a via middle scenario, disposing contact pads on the bottom surface of the interposer substrate 920 includes thinning the interposer substrate from a backside to reveal the molding material in a saw street area, and then forming the TSVs from the backside to the front surface of the interposer substrate.

In some implementations, the stack of semiconductor die may include a glass cover placed above an optical sensor die. In such implementations, the method may include disposing a non-transparent black coating on an edge portion of a top surface (and/or on a bottom surface) of the glass cover to, for example, block light incident on the optical sensor die at small angles of incidence.

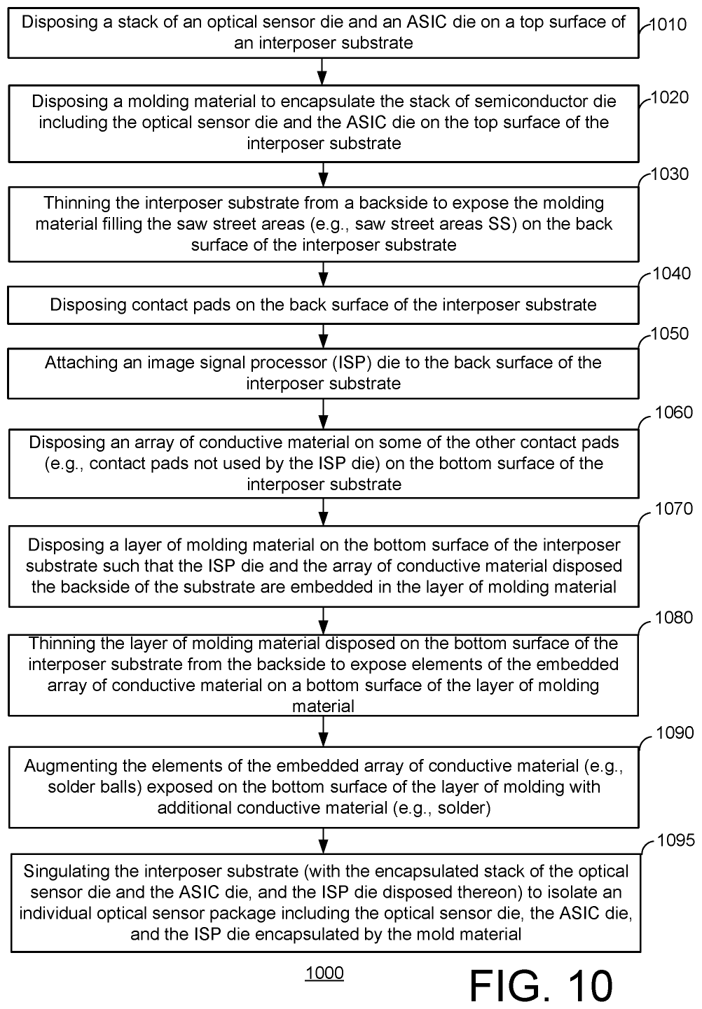

FIG. 10 shows an example method 1000 for fabricating an optical sensor package (e.g., an imager ball grid array (ieBGA) package). The optical sensor package may include a stack of semiconductor die including an optical sensor die disposed above and coupled to an ASIC die, and further include embedded image signal processor (ISP) die. The optical sensor die may, for example, be a contact image sensor (CIS) configured as a chip scale package (CIS CSP). The ASIC die may include backside through-semiconductor vias (BTSV) for electrical connections to the optical sensor die. The optical sensor die may be arranged as a stack of the optical sensor die and the ASIC die (e.g., a BTSV CIS CSP). The stack may further include an array (e.g., BGA) of conductive material disposed on a bottom surface of the stack.

Method 1000 includes disposing a stack of semiconductor die including an optical sensor die and an ASIC die on a top surface of an interposer substrate (1010). Disposing the stack of the optical sensor die and the ASIC die on the top surface of the interposer substrate 1010 includes bonding the stack to the contact pads on the top surface of interposer substrate using the array of conductive material disposed on the bottom surface of the stack.

Method 1000 further includes disposing a molding material to encapsulate the stack of semiconductor die including the optical sensor die and the ASIC die on the top surface of the interposer substrate (1020). The molding material is disposed on all four sides of the stack above the top surface of interposer substrate and fills in areas of the substrate (e.g., saw street areas SS) that have been etched to a depth d below the top surface of the interposer substrate.

Method 1000 further includes thinning the interposer substrate from a backside to expose the molding material filling the saw street areas (e.g., saw street areas SS) on the back surface of the interposer substrate (1030). The thinning may also expose at least one TSV (that may be present in the interposer substrate) on the back surface of the interposer substrate. If no TSVs are present, method 1000 includes forming at least one TSV connecting the back surface of the interposer substrate to the front surface of the interposer substrate.

Method 1000 further includes disposing contact pads on the back surface of the interposer substrate (1040) and attaching an image signal processor (ISP) die to the back surface of the interposer substrate (1050). The ISP die may, for example, be flip chip mounted on the contact pads disposed on the back surface of the interposer substrate. Method 1000 further includes disposing an array of conductive material on some of the other contact pads (e.g., contact pads not used by the ISP die) on the bottom surface of the interposer substrate (1060). Elements of the array of conductive material may, for example, include solder bumps, micro bumps, or copper balls, etc.

Method 1000 further includes disposing a layer of molding material on the bottom surface of the interposer substrate such that the ISP die and the array of conductive material disposed the backside of the substrate are embedded in the layer of molding material (1070), and thinning the layer of molding material disposed on the bottom surface of the interposer substrate from the backside to expose elements of the embedded array of conductive material on a bottom surface of the layer of molding material (1080). Method 1000 further includes augmenting the elements of the embedded array of conductive material (e.g., solder balls) exposed on the bottom surface of the layer of molding with additional conductive material (e.g., solder) (1090). The elements of the embedded array of conductive material (e.g., solder balls) with additional conductive material can form the external input/output contacts of the package.

Method 1000 further includes singulating the interposer substrate (with the encapsulated stack of the optical sensor die and the ASIC die, and the ISP die disposed thereon) to isolate an individual optical sensor package including the optical sensor die, the ASIC die, and the ISP die encapsulated by the mold material (1095).

In method 1000, singulating the interposer substrate with encapsulated stack of the optical sensor die and the ASIC die, and the ISP die disposed thereon includes singulating through pre-identified saw street areas on the interposer substrate.

In method 1000, electrically connecting the contact pads on the top surface of interposer substrate and the contact pads on the bottom surface of the interposer substrate may include utilizing electrically conductive TSVs for electrically connecting the top surface of interposer substrate and the bottom surface of the interposer substrate.

In some example implementations, under a via first scenario, the TSVs may be prebuilt and extend from the front surface of the interposer substrate partially through a thickness of the interposer substrate toward a back surface of the interposer substrate. In such implementations, in method 1000, disposing contact pads on the bottom surface of the interposer substrate, includes thinning the interposer substrate from a backside to expose the TSVs on the bottom surface of the interposer substrate.

In some implementations, under a via last or a via middle scenario, disposing contact pads on the bottom surface of the interposer substrate includes thinning the interposer substrate from a backside to reveal the molding material in a saw street area, and then forming the TSVs from the backside to the front surface of the interposer substrate.

In some example implementations, in method 1000, attaching the image signal processor (ISP) die to the back surface of the interposer substrate 1050 may further include attaching a heat spreader to the attached ISP die. The heat spreader may have external input/output contacts of the package made, for example, of solder.

In some example implementations, in method 1000, attaching the image signal processor (ISP) die to the back surface of the interposer substrate 1050 may further include forming at least one through-mold via (TMV) in the layer of molding material disposed on the bottom surface and at least one pass through via in the ISP die to provide an electrical connection from an external input/output terminal (e.g., a solder ball) of the package to the stack of the optical sensor die and the ASIC die.

In some example implementations, in method 1000, attaching the image signal processor (ISP) die to the back surface of the interposer substrate 1050 may further include forming at least one through-mold via (TMV) in the layer of molding material disposed on the bottom surface and at least one pass through via in the ISP die to provide an electrical connection from an external input/output terminal (e.g., a solder ball) of the package to the stack of the optical sensor die and the ASIC die.

While certain features of the described implementations have been illustrated as described herein, many modifications, substitutions, changes, and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

It will be understood that, in the foregoing description, when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising,” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

What is claimed is:

1. A package comprising:
an interposer substrate including at least one through-substrate via (TSV) electrically connecting a top surface of the interposer substrate to a bottom surface of the interposer substrate;
at least one semiconductor die having a top side, a bottom side, and a sidewall, the at least one semiconductor die being disposed on the interposer substrate with the bottom side electrically coupled to the top surface of the interposer substrate;
a molding material disposed on at least on a portion of the at least one semiconductor die; and
an array of conductive material disposed on the bottom surface of the interposer substrate, the array of conductive material forming external contacts of the package.

2. The package of claim 1, wherein at least one semiconductor die has a width, and the interposer substrate has a width that is greater than the width of the at least one semiconductor die.

3. The package of claim 1, wherein at least one semiconductor die is an optical sensor die, and the package further includes a glass cover disposed above the top side of the optical sensor die.

4. The package of claim 3 further comprising:
a non-transparent black coating disposed on an edge portion of the glass cover disposed above the top side of the optical sensor die.

5. The package of claim 1, wherein the array of conductive material disposed on the bottom surface of the interposer substrate is a ball grid array of solder.

6. The package of claim 1, wherein the at least one semiconductor die is a stack of an optical sensor die disposed above an application-specific integrated circuit (ASIC) die, the ASIC die including at least one backside through-semiconductor via (BTSV) for electrical connections to the optical sensor die.

7. A package comprising:
an interposer substrate including at least one through-substrate via electrically connecting a top surface of the interposer substrate to a bottom surface of the interposer substrate;
at least one semiconductor die disposed on the interposer substrate with a bottom side of the at least one semiconductor die being electrically coupled to the top surface of the interposer substrate;
a layer of molding material disposed on the bottom surface of the interposer substrate, the layer of molding material including at least one through-mold via for electrical connection to the interposer substrate;
an image signal processing (ISP) die embedded in the layer of molding material; and
an array of conductive material disposed on a bottom surface of the layer of molding material, the array of conductive material forming external contacts of the package.

8. The package of claim 7, wherein the image signal processing (ISP) die embedded in the layer of molding material is flip chip mounted on the bottom surface of the interposer substrate.

9. The package of claim 7, wherein the at least one semiconductor die has a width, and the interposer substrate has a width that is greater than the width of the at least one semiconductor die.

10. The package of claim 7, wherein at least one semiconductor die is an optical sensor die, and the package further includes a glass cover disposed above a top side of the optical sensor die.

11. The package of claim 10 further comprising:
a non-transparent black coating disposed on an edge portion of the glass cover disposed above the top side of the optical sensor die.

12. The package of claim 7, wherein the array of conductive material disposed on the bottom surface of the interposer substrate is a ball grid array of solder.

13. The package of claim 7, wherein the at least one semiconductor die is a stack of an optical sensor die disposed above an application-specific integrated circuit (ASIC) die, the ASIC die including at least one backside through-semiconductor via (BTSV) for electrical connections to the optical sensor die.

14. A method, comprising:
disposing a stack of semiconductor die on a top surface of an interposer substrate, the top surface of the interposer substrate including contact pads;
disposing contact pads on a bottom surface of the interposer substrate;
electrically connecting the contact pads on the top surface of interposer substrate and the contact pads on the bottom surface of the interposer substrate; and
disposing an array of conductive material on the contact pads on the bottom surface of the interposer substrate, the array of conductive material forming external contacts of the stack of the semiconductor die.

15. The method of claim 14 further comprising:
disposing molding material on at least four sides of the stack of the semiconductor die to encapsulate the stack of the semiconductor die disposed on the top surface of the interposer substrate.

16. The method of claim 15 further comprising:
singulating the interposer substrate with the stack of the semiconductor die disposed encapsulated thereon to isolate an individual optical sensor package including the stack of the semiconductor die encapsulated by the molding material.

17. The method of claim 16, singulating the interposer substrate with the encapsulated stack of the semiconductor die encapsulated thereon includes singulating through pre-identified saw street areas on the interposer substrate.

18. The method of claim 14, wherein disposing the stack of the semiconductor die on the top surface of an interposer substrate includes bonding the stack of the semiconductor die to the contact pads on the top surface of interposer substrate using the array of conductive material disposed on the bottom surface of the stack of the semiconductor die.

19. The method of claim 14, wherein electrically connecting the contact pads on the top surface of interposer substrate and the contact pads on the bottom surface of the interposer substrate includes utilizing at least one through-substrate via for electrically connecting the top surface of interposer substrate and the bottom surface of the interposer substrate.

20. The method of claim 14, wherein the stack of the semiconductor die includes a glass cover placed above an optical sensor die and the method further includes disposing a non-transparent black coating on an edge portion of at least one of a top surface or a bottom surface of the glass cover.

21. A method comprising:
disposing a stack of semiconductor die on a top surface of an interposer substrate, the stack of the semiconductor die including an optical sensor die and an application-specific integrated circuit (ASIC) die;
disposing a molding material to encapsulate the stack of the semiconductor die including the optical sensor die and the ASIC die on the top surface of the interposer substrate, the molding material being disposed on four sides of the stack of the semiconductor die above the top surface of interposer substrate and filling in saw street areas of the interposer substrate that have been etched to a depth below the top surface of the interposer substrate;
thinning the interposer substrate from a backside to expose the molding material filling the saw street areas on a back surface of the interposer substrate;
disposing contact pads on the back surface of the interposer substrate;
attaching an image signal processor (ISP) die to the back surface of the interposer substrate;
disposing an array of conductive material on contact pads not used by the ISP die on a bottom surface of the interposer substrate;
disposing a layer of molding material on the bottom surface of the interposer substrate such that the ISP die, and the array of conductive material disposed the backside of the interposer substrate are embedded in the layer of molding material;
thinning the layer of molding material disposed on the bottom surface of the interposer substrate from the backside to expose elements of the embedded array of conductive material on a bottom surface of the layer of molding material;
augmenting the elements of the embedded array of conductive material exposed on the bottom surface of the layer of molding with additional conductive material, the embedded array of conductive material forming external input/output contacts of the stack of the semiconductor die; and
singulating the interposer substrate (with the encapsulated stack of the optical sensor die and the ASIC die, and the ISP die disposed thereon) to isolate an individual optical sensor package including the optical sensor die, the ASIC die, and the ISP die encapsulated by the molding material.

22. The method of claim 21, wherein singulating the interposer substrate with encapsulated stack of the optical sensor die and the ASIC die, and the ISP die disposed thereon includes singulating through pre-identified saw street areas on the interposer substrate that are filled with the molding material.

23. The method of claim 21, wherein thinning the interposer substrate from the backside to expose the molding material filling the saw street areas on the back surface of the interposer substrate includes exposing at least one through-substrate via present in the interposer substrate on the back surface of the interposer substrate.
